(19) United States
(12) Patent Application Publication
(10) Pub. No.: US 2026/0302748 A1
(43) Pub. Date: Oct. 1, 2026

(54) CIRCUIT ASSEMBLY

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Tatsuya MANO, Osaka-shi, Osaka (JP); Yoshiyuki USUI, Osaka-shi, Osaka (JP)

(73) Assignees: AutoNetworks Technologies, Ltd., Yokkaichi-shi, Mie (JP); Sumitomo Electric Industries, Ltd., Osaka-shi, Osaka (JP); Sumitomo Wiring Systems, Ltd., Yokkaichi-shi, Mie (JP)

(21) Appl. No.: 19/474,827

(22) PCT Filed: Mar. 27, 2024
(86) PCT No.: PCT/JP2024/012143

§ 371 Date: Oct. 13, 2025

(30) Foreign Application Priority Data
Apr. 17, 2023 (JP) 2023-067065

(51) Int. Cl. H02G 3/16

(52) U.S. Cl. CPC H02G 3/16

(57) ABSTRACT

A circuit assembly includes a body and an electrical component device to be fixed to the body. In the circuit assembly, the body has first busbars, second busbars, and a case that accommodates the first busbars and the second busbars. A lid of the case has a first opening portion into which the electrical component device is insertable. The electrical component device includes relays, one-side busbars provided at ends on one side of the relays, and other-side busbars provided at ends on the other side of the relays. The one-side busbars are fixed to the first busbars by first screws. The other-side busbars are fixed to the second busbars by second screws.

### CROSS-REFERENCE TO RELATED APPLICATIONS

This application is the U.S. national stage of PCT/JP2024/012143 filed on Mar. 27, 2024, which claims priority of Japanese Patent Application No. JP 2023-067065 filed on Apr. 17, 2023, the contents of which are incorporated herein.

### TECHNICAL FIELD

The present disclosure relates to a circuit assembly.

### BACKGROUND

JP 2017-143611A discloses an electrical junction box that accommodates a plurality of electronic components in a housing.

When attaching or detaching an electronic component to or from this electrical junction box, an upper cover needs to be removed, which is time consuming.

The present disclosure has been completed based on the above circumstances, and an object thereof is to provide a circuit assembly in which components accommodated in a case can be easily replaced.

### SUMMARY

A circuit assembly comprises: a body; and an electrical component device to be fixed to the body, wherein the body includes: a first busbar, a second busbar, and a case configured to accommodate the first busbar and the second busbar, the case has an opening portion into which the electrical component device is insertable, the electrical component device includes: an electrical component, a one-side busbar provided at one end of the electrical component, and an other side busbar provided at another end of the electrical component, the one-side busbar is fixed to the first busbar by a first screw, and the other side busbar is fixed to the second busbar by a second screw.

### Advantageous Effects

According to the present disclosure, components accommodated in the case can be easily replaced.

### BRIEF DESCRIPTION OF DRAWINGS

FIG. 1 is an exploded perspective view of a circuit assembly according to Embodiment 1.

FIG. 2 is a perspective view showing a state in which a conductive path busbar is attached to a case body.

FIG. 3 is a perspective view of a lid.

FIG. 4 is a perspective view showing a state in which a lid is attached to a case body, and a fuse, a precharge relay, a resistor, and a current detection unit are attached to the lid.

FIG. 5 is a perspective view showing electrical components.

FIG. 6 is a perspective view showing the relay and a first insulating member.

FIG. 7 is a plan view showing a state in which the first insulating member with the relay attached thereto is attached to the case.

FIG. 8 is a cross-sectional view taken along line A-A in FIG. 7.

### DETAILED DESCRIPTION OF PREFERRED EMBODIMENTS

First, embodiments of the present disclosure will be listed and described below.

In a first aspect, a circuit assembly comprises: a body; and an electrical component device to be fixed to the body, wherein the body includes: a first busbar, a second busbar, and a case configured to accommodate the first busbar and the second busbar, wherein the case has an opening portion into which the electrical component device is insertable, the electrical component device includes: an electrical component, a one-side busbar provided at one end of the electrical component, and an other side busbar provided at another end of the electrical component, the one side busbar is fixed to the first busbar by a first screw, and the other-side busbar is fixed to the second busbar by a second screw.

With the circuit assembly according to the first aspect, the electrical component can be attached to the case through the opening portion, eliminating the need to perform an operation such as opening the case.

In a second aspect, the circuit assembly according to the first aspect, wherein the one-side busbar is fastened together with the first busbar by the first screw, and the other side busbar is fastened together with the second busbar by the second screw.

The circuit assembly according to the second aspect can ensure that the one-side busbar is in electrical conduction with the first busbar, and the other-side busbar is in electrical conduction with the second busbar.

In a third aspect, the circuit assembly according to the first aspect, wherein the electrical component device includes an insulating member configured to cover at least a portion of the electrical component from outside of the case in a state in which the electrical component device is fixed to the body.

With the circuit assembly according to the third aspect, the insulating member can make it unlikely for the electrical components to be touched.

In a fourth aspect, the circuit assembly according to the third aspect, wherein the insulating member has a first exposure hole allowing a head of the first screw to be exposed to the outside, and a second exposure hole allowing a head of the second screw to be exposed to the outside.

With the circuit assembly according to the fourth aspect, the first screw and the second screw can be attached or detached via the first exposure hole and the second exposure hole.

In a fifth aspect, the circuit assembly according to the third aspect, wherein there are a plurality of the opening portions, including a first opening portion and a second opening portion, there are a plurality of the insulating members, including a first insulating member and a second insulating member, there are a plurality of the electrical components, including a first electrical component and a second electrical component, the first insulating member covers the first electrical component inserted into the first opening portion from the outside, and the second insulating member covers the second electrical component inserted into the second opening portion from the outside.

With the circuit assembly according to the fifth aspect, in a state in which one electrical component is covered with the insulating member, the other electrical component can be exposed. Therefore, an electrical component that needs to be exposed can be exposed while an electrical component that does not need to be exposed is covered.

In a sixth aspect, the circuit assembly according to the third aspect, wherein the electrical component is fixed to the insulating member by a third screw.

The circuit assembly according to the sixth aspect can have a configuration in which an electrical component is handled by holding an insulating member, without coming into direct contact with the electrical component.

In a seventh aspect, the circuit assembly according to the third aspect, the insulating member has one or more recesses or through holes serving as holding assistants.

With the circuit assembly according to claim the seventh aspect, the insulating member can be easily attached to or detached from the case.

### Embodiment 1

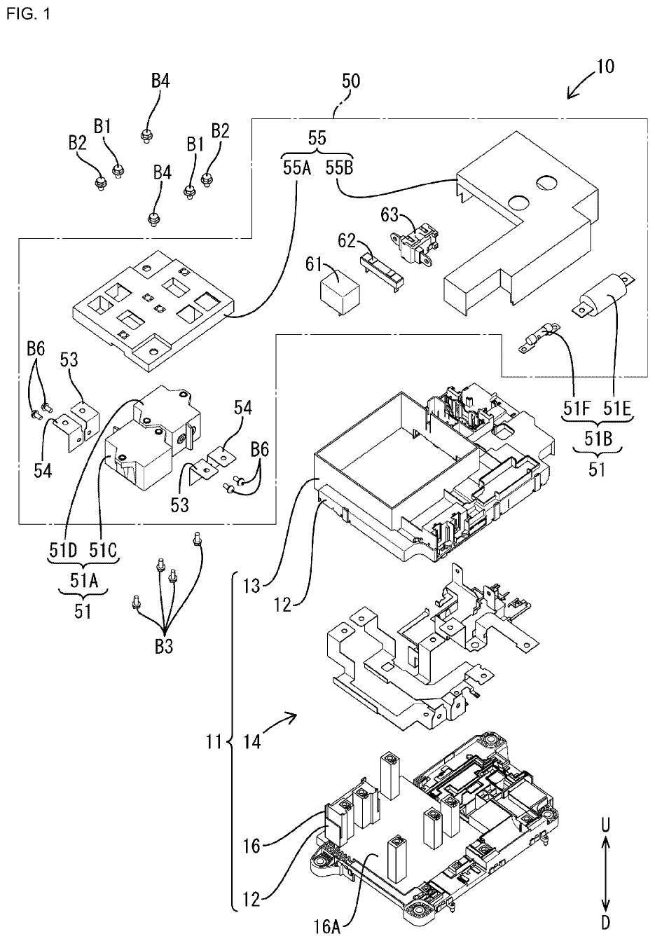

A circuit assembly 10 according to Embodiment 1 of the present disclosure will be described with reference to FIGS. 1 to 8. In Embodiment 1, the “upper side” and “lower side” in the drawings are represented by “U” and “D”, respectively.

The circuit assembly 10 is mounted in a vehicle (not shown) such as an electric automobile or a hybrid automobile, and supplies electric power from a power source to a load. As shown in FIG. 1, the circuit assembly 10 includes a body 11 and an electrical component device 50 that is attached to and housed in the body 11.

### Configuration of Body

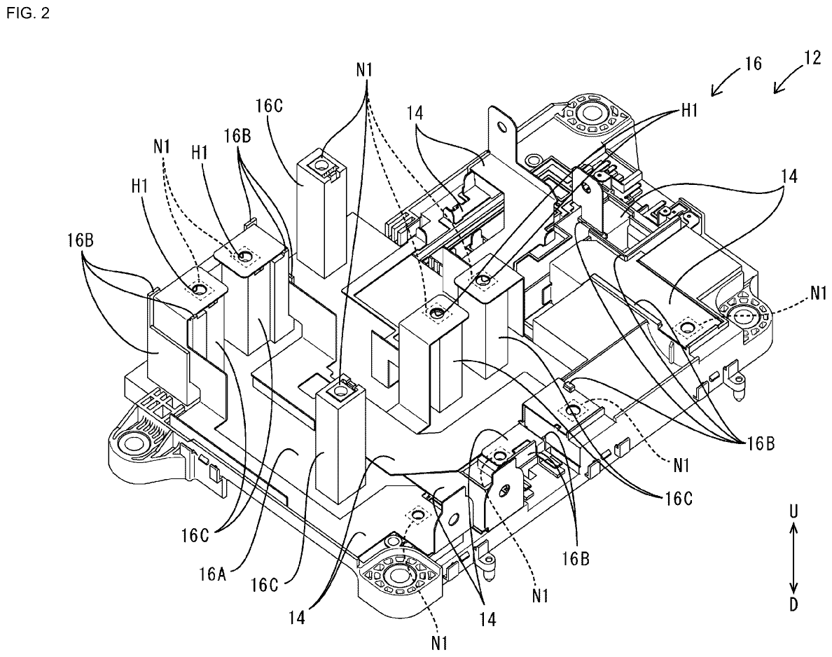

The body 11 has a case 12 and conductive path busbars 14. The case 12 is made of an insulating synthetic resin, for example. The case 12 includes a case body 16 and a lid 13. As shown in FIG. 2, the case body 16 has a bottom wall 16A. The bottom wall 16A is provided with a plurality of bosses 16C protruding upward. A nut N1 such as an insert nut is embedded in an upper end portion of each boss 16C with the axis of the screw hole extending in the up-down direction.

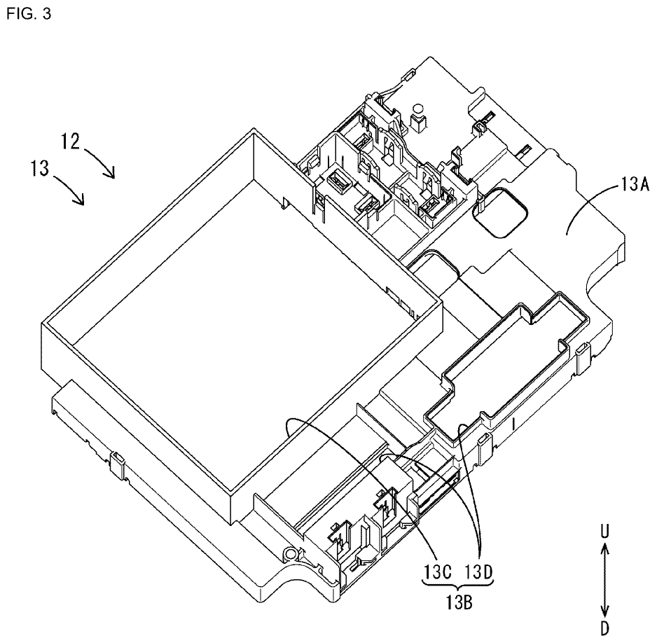

The lid 13 is made of an insulating synthetic resin, for example. As shown in FIG. 3, the lid 13 includes a closing wall 13A and opening portions 13B that extend through the closing wall 13A in the plate thickness direction. The opening portions 13B include one first opening portion 13C and two second opening portions 13D.

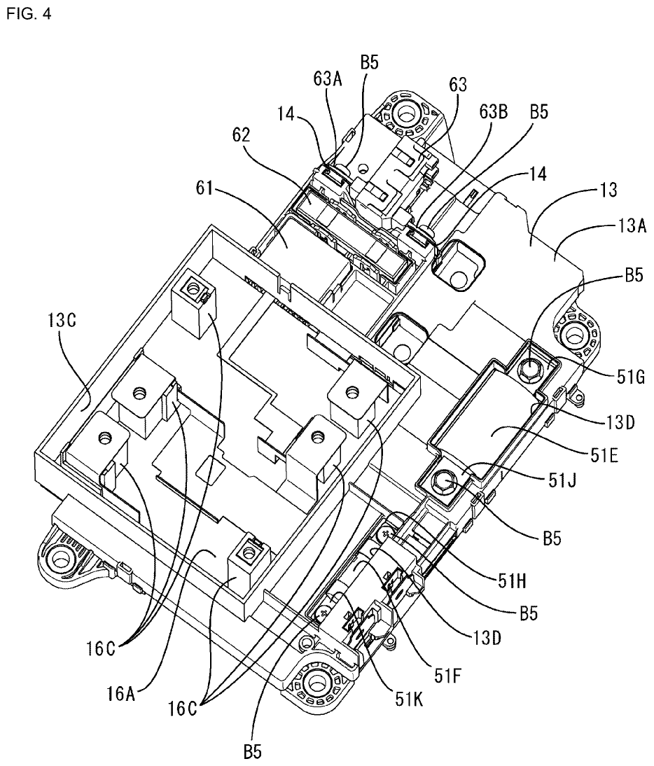

The lid 13 is disposed such that the closing wall 13A overlaps the bottom wall 16A from above (see FIG. 4). For example, the lid 13 is fixed to the case body 16 by snap-fitting, a screw, or the like. In a plan view of the lid 13 attached to the case body 16 from above, the bosses 16C are disposed within a region in which the first opening portion 13C is formed (see FIG. 4). The two second opening portions 13D are formed adjacent to the first opening portion 13C.

The conductive path busbars 14 are members that are accommodated in the case 12 and constitute a conductive path between the power source and the load. The conductive path busbars 14 are each formed by pressing a flat metal plate. As shown in FIG. 2, the conductive path busbars 14 are disposed at separate locations in the case 12. The conductive path busbars 14 are prevented from being displaced relative to the bottom wall 16A by a plurality of guide portions 16B provided on the bottom wall 16A. The conductive path busbars 14 have insertion holes H1 that extend in the plate thickness direction. A portion of each of the conductive path busbars 14 is disposed to cover, from above, the nut N1 embedded in the boss 16C. The insertion hole H1 is disposed coaxially with the threaded hole of the nut N1.

### Configuration of Electrical Component Device

As shown in FIG. 1, the electrical component device 50 includes electrical components 51, a precharge relay 61, a resistor 62, an electric current detection unit 63, one-side busbars 53, other side busbars 54, and an insulating member 55. The electrical components 51 include a first electrical component 51A and a second electrical component 51B. The first electrical component 51A has a plurality of relays 51C and 51D. The second electrical component 51B has a plurality of fuses 51E and 51F. The insulating member 55 has a first insulating member 55A and a second insulating member 55B.

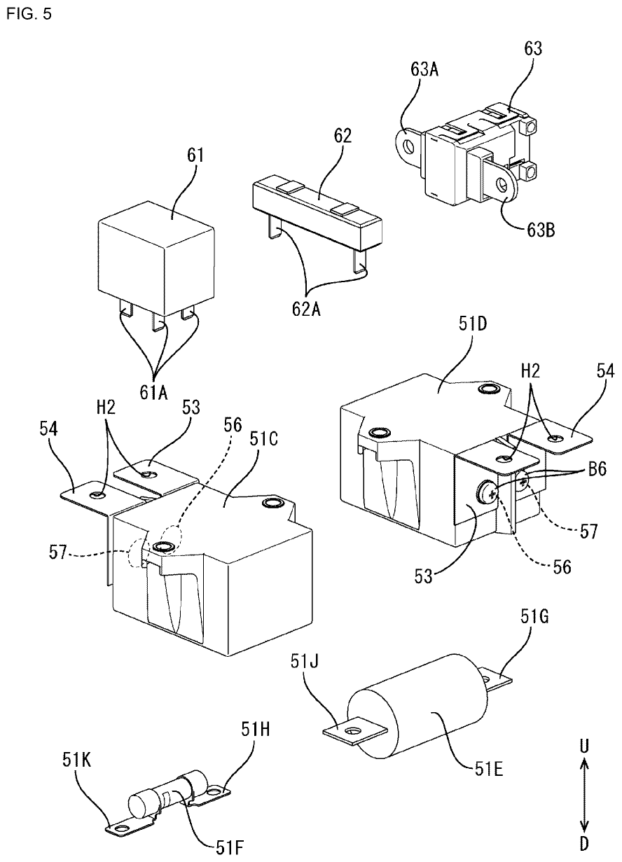

The relays 51C and 51D are constituted by, for example, mechanical relays. As shown in FIG. 5, each of the relays 51C and 51D has a pair of terminals 56 and 57, and switches between an allowable state, in which a current flow between the pair of terminals 56 and 57 is allowed, and a blocking state, in which the current flow is blocked. The relays 51C and 51D are configured such that a control unit (not shown) can execute control such that the relays 51C and 51D switch between the allowable state and the blocking state.

The fuses 51E and 51F are constituted by, for example, thermal fuses. Flat plate-shaped one-side busbars 51G and 51H are provided at one end of the fuses 51E and 51F, respectively, and flat plate-shaped other-side busbars 51J and 51K are provided at the other end thereof. The fuse 51E and the fuse 51F are respectively disposed in the two second opening portions 13D of the lid 13 attached to the case body 16 (see FIG. 4).

The one-side busbar 51G of the fuse 51E and one of the conductive path busbars 14 are together fastened to one of the nuts N1 (see FIG. 2) provided on the case body 16, by a fifth screw B5 (see FIG. 4). The other side busbar 51J of the fuse 51E and one of the conductive path busbars 14 other than the one fastened with the one-side busbar 51G are together fastened to another one of the nuts N1 (see FIG. 2) provided on the case body 16 (see FIG. 4), by another fifth screw B5. The conductive path busbar 14 fastened together with the one-side busbar 51G is a first busbar, and the conductive path busbar 14 fastened together with the other-side busbar 51J is a second busbar.

The one-side busbar 51H of the fuse 51F and one of the conductive path busbars 14 are together fastened to one of the nuts N1 (see FIG. 2) provided on the case body 16, by a fifth screw B5 (see FIG. 4). The other side busbar 51K of the fuse 51F and one of the conductive path busbars 14 other than the one fastened with the one-side busbar 51H are together fastened to another one of the nuts N1 (see FIG. 2) provided on the case body 16 (see FIG. 4), by another fifth screw B5. The conductive path busbar 14 fastened together with the one-side busbar 51H is the first busbar, and the conductive path busbar 14 fastened together with the other-side busbar 51K is the second busbar.

Similar to the relays 51C and 51D, the precharge relay 61 may be constituted by, for example, a mechanical relay. The precharge relay 61 is configured such that a control unit (not shown) can execute control such that the precharge relay 61 switches between the allowable state and the blocking state. The resistor 62 is connected in series to the precharge relay 61. For example, the precharge relay 61 and the resistor 62 are arranged so as to be placed on the lid 13 (see FIG. 4), and the busbars 61A and 62A thereof are configured to come into elastic contact with the corresponding conductive path busbars 14.

The electric current detection unit 63 has, for example, a resistor and a differential amplifier, and is configured to be able to output a value indicating the current flowing through the conductive path busbar 14 (specifically, an analog voltage corresponding to the value of the current flowing through the conductive path busbar 14) as a current value. A one-side busbar 63A is provided at one end of the electric current detection unit 63, and an other side busbar 63B is provided at the other end thereof. The electric current detection unit 63 is arranged so as to be placed on the lid 13 (see FIG. 4). The one-side busbar 63A is fastened together with the corresponding conductive path busbar 14 that passes through the closing wall 13A of the lid 13 by a fifth screw B5 (see FIG. 4). The other side busbar 63B is separate from the one-side busbar 63A, and is fastened together with the corresponding conductive path busbar 14 that passes upward through the closing wall 13A of the lid 13 by a fifth screw B5 (see FIG. 4).

The one-side busbars 53 are each formed by pressing a flat metal plate. End portions on one side of the one-side busbars 53 are electrically connected to the terminals 56 on the one end side of the relays 51C and 51D by sixth screws B6. End portions on the other side of the one-side busbars 53 each have an insertion hole H2 that extends in the plate thickness direction.

The other side busbars 54 are each formed by pressing a flat metal plate. End portions on one side of the other side busbars 54 are electrically connected to the terminals 57 on the other end side of the relays 51C and 51D by sixth screws B6. End portions on the other side of the other side busbars 54 each have an insertion hole H2 that extends in the plate thickness direction.

In the present disclosure, the expression “electrically connected” preferably means a configuration in which connection targets are connected in a mutually conductive state (a state in which a current can flow) such that potentials of both connection targets are equal to each other. However, the present disclosure is not limited to this configuration. For example, the expression “electrically connected” may refer to a configuration in which two connection targets can be electrically connected in a state in which an electrical component is interposed between the two connection targets.

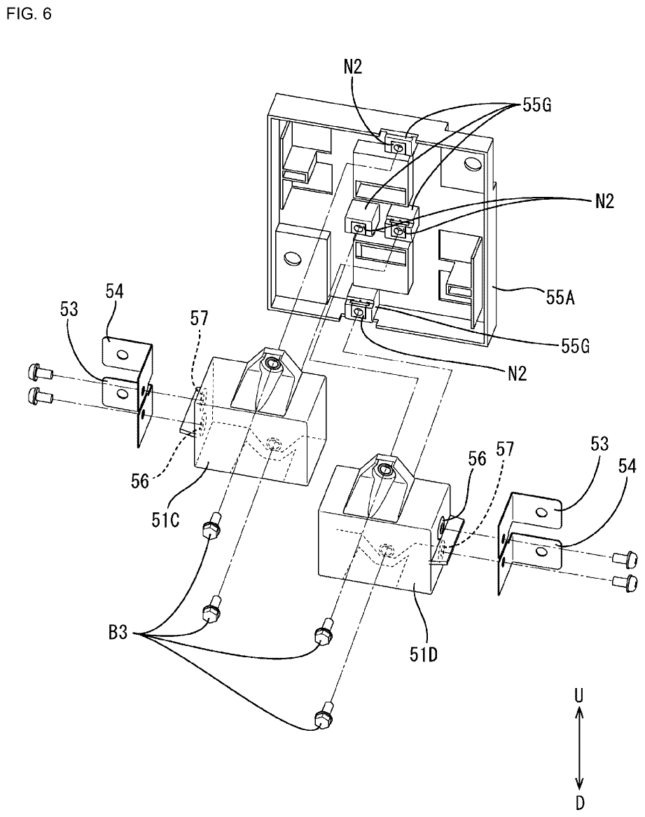

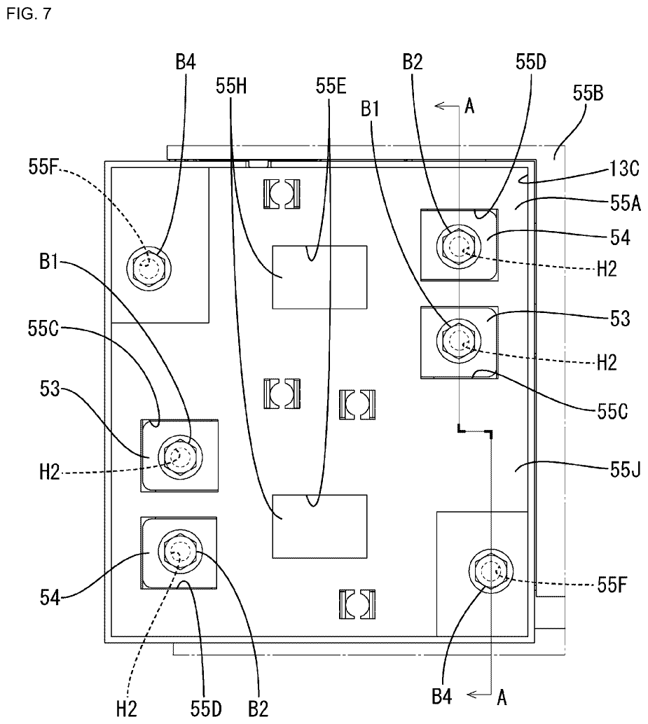

The first insulating member 55A and the second insulating member 55B are made of, for example, an insulating synthetic resin. As shown in FIG. 6, an outer shape of the first insulating member 55A is a flattened rectangle. The outer dimensions of the first insulating member 55A in a plan view from above are slightly smaller than the outer dimensions of the first opening portion 13C of the lid 13 (see FIG. 7). The first insulating member 55A has a plurality of protrusions 55G that protrude downward. A nut N2 such as an insert nut is embedded in a lower end portion of each protrusion 55G with the axis of the screw extending in the up-down direction.

As shown in FIG. 7, the first insulating member 55A has two first exposure holes 55C, two second exposure holes 55D, two through holes 55E, and two screw insertion holes 55F, which all extend in the plate thickness direction. The first exposure holes 55C and the second exposure holes 55D are arranged adjacent to each other so as to form pairs, and each have a rectangular outer shape.

The two through holes 55E are disposed in a central portion of the first insulating member 55A in a plan view from above. Each through hole 55E has a bottom wall 55H formed below a front wall 55J of the first insulating member 55A, and connection walls are provided rising from the outer peripheral edge of the bottom wall 55H, and upper ends of the connection walls are continuous with the front wall 55J. A connection wall is not provided at one of the four sides of the bottom wall 55H, and accordingly, the through hole 55E extends through the first insulating member 55A in the up-down direction. Two screw insertion holes 55F are respectively disposed near two opposite corners among the four corners of the first insulating member 55A.

As shown in FIG. 1, the outer shape of the second insulating member 55B is an L-shape. The second insulating member 55B is fixed to the case body 16 by snap-fitting, a screw, or the like so as to cover the fuses 51E and 51F disposed in the second opening portions 13D, and the precharge relay 61, the resistor 62, and the electric current detection unit 63 that are placed on the lid 13. The second insulating member 55B is disposed in the case body 16 so as to extend along two of the four sides of the first opening portion 13C (see FIG. 7).

As shown in FIG. 6, the relays 51C and 51D are fixed to the first insulating member 55A by fastening third screws B3 to nuts N2 of the protrusions 55G. In a state in which the relays 51C and 51D are fixed to the first insulating member 55A, the other end portions of the one-side busbars 53 are disposed to block the first exposure holes 55C, and the other end portions of the other side busbars 54 are disposed to block the second exposure holes 55D (see FIG. 7). The insertion holes H2 formed in the other end portions of the one-side busbars 53 are disposed to face the first exposure holes 55C (see FIG. 7). The insertion holes H2 formed in the other end portions of the other side busbars 54 are disposed to face the second exposure holes 55D (see FIG. 7).

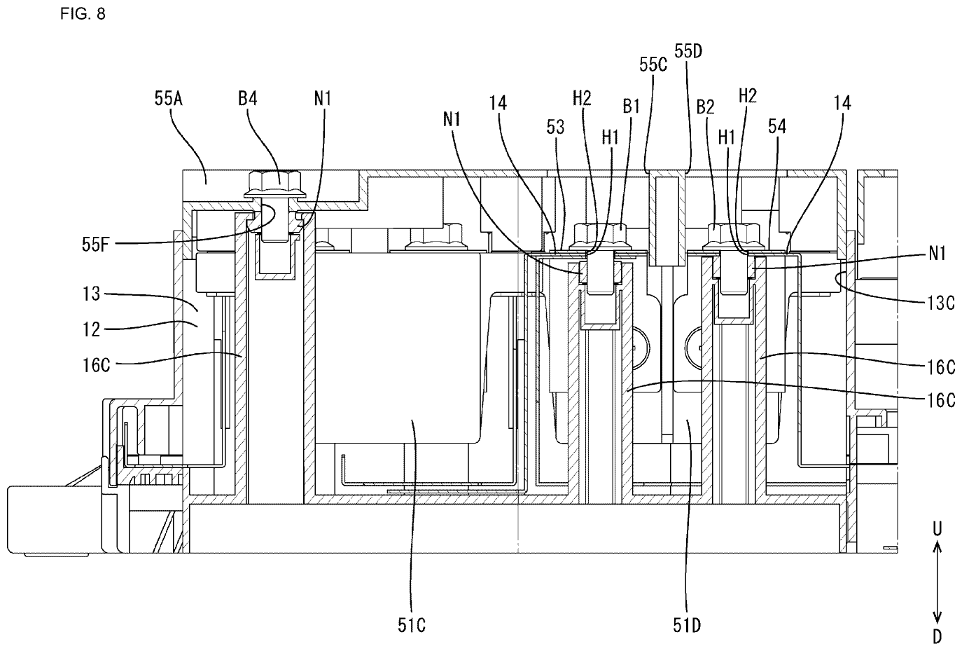

As shown in FIG. 8, the relays 51C and 51D attached to the first insulating member 55A are inserted into the first opening portion 13C of the lid 13 and accommodated in the case 12. Specifically, the relays 51C and 51D are accommodated in the first opening portion 13C of the lid 13 from above, while maintaining an orientation in which the first insulating member 55A is disposed above the relays 51C and 51D. At this time, the relays 51C and 51D can be accommodated in the case 12 by moving the relays 51C and 51D down into the case 12, and thus the operation of accommodating them in the case 12 can be easily completed.

At this time, the other end portions of the one side busbars 53 are disposed to overlap the corresponding conductive path busbars 14 covering the upper ends of the bosses 16C, and the other end portions of the other side busbars 54 are disposed to overlap the corresponding conductive path busbars 14 covering the upper ends of the bosses 16C. The first insulating member 55A is disposed such that the lower half thereof is inserted into the first opening portion 13C. The first exposure holes 55C of the first insulating member 55A, the insertion holes H2 of the one-side busbars 53, the insertion holes H1 of the conductive path busbars 14, and the screw holes of the nuts N1 of the bosses 16C overlap each other to communicate with each other. At the same time, the second exposure holes 55D of the first insulating member 55A, the insertion holes H2 of the other side busbars 54, the insertion holes H1 of the conductive path busbars 14, and the screw holes of the nuts N1 of the bosses 16C overlap each other to communicate with each other.

First screws B1 are inserted through the first exposure holes 55C, the insertion holes H2, and the insertion holes H1, which overlap each other to communicate with each other, and the first screws B1 are fastened to the nuts N1 embedded in the bosses 16C. At the same time, second screws B2 are inserted through the second exposure holes 55D, the insertion holes H2, and the insertion holes H1, which overlap each other to communicate with each other, and the second screws B2 are fastened to the nuts N1 embedded in the bosses 16C. As a result, the one-side busbars 53 are fastened together with the conductive path busbars 14 by the first screws B1 and fixed thereto. The other side busbars 54 are fastened together with the conductive path busbars 14 by the second screws B2 and fixed thereto. The conductive path busbars 14 fastened together with the one-side busbars 53 are the first busbars, and the conductive path busbars 14 fastened together with the other side busbars 54 are the second busbars. Further, fourth screws B4 are inserted through the screw insertion holes 55F of the first insulating member 55A, and the fourth screws B4 are fastened to the corresponding nuts N1 embedded in the bosses 16C.

The fuses 51E and 51F are respectively disposed in the second opening portions 13D, and the one-side busbars 51G and 51H are fastened together with the corresponding conductive path busbars 14 by screwing the fifth screws B5 into the nuts N1, while the other side busbars 51J and 51K are fastened together with the corresponding conductive path busbars 14 by screwing the fifth screws B5 into the nuts N1 (see FIG. 4). The fuses 51E and 51F disposed in the second opening portions 13D, and the precharge relay 61, the resistor 62, and the electric current detection unit 63 that are placed on the lid 13 are covered with the second insulating member 55B, and the second insulating member 55B is attached to the case body 16. In this manner, the electrical component device 50 is fixed to the case 12 of the body 11.

In a state in which the electrical component device 50 is fixed to the case 12 of the body 11, the first insulating member 55A is disposed to cover the relays 51C and 51D from the outside of the case 12 and close the first opening portion 13C. The heads of the first screws B1 fastened to the nuts N1 of the bosses 16C of the case 12 are exposed to the outside through the first exposure holes 55C. The heads of the second screws B2 fastened to the nuts N1 of the bosses 16C of the case 12 are exposed to the outside through the second exposure holes 55D. The heads of the fourth screws B4 fastened to the nuts N1 of the bosses 16C of the case 12 are exposed to the outside.

When the electrical component device 50 is to be removed from the case 12, the first screws B1, the second screws B2, and the fourth screws B4 are loosened and removed. Then, the first insulating member 55A is held by fingers inserted into two through holes 55E of the first insulating member 55A, and the first insulating member 55A is pulled up. As a result, the relays 51C and 51D, the one-side busbars 53, and the other side busbars 54 can be removed from the case 12 together with the first insulating member 55A.

When the fuses 51E and 51F are to be removed from the case 12, first, the second insulating member 55B is removed from the case body 16. Then, the fifth screws B5 fastened to the one-side busbars 51G and 51H and the other side busbars 51J and 51K of the fuses 51E and 51F are loosened and removed. As a result, the fuses 51E and 51F can be removed from the case 12.

When the electric current detection unit 63 is to be removed from the case 12, the fifth screws B5 fastened to the one-side busbar 63A and the other side busbar 63B of the electric current detection unit 63 are loosened and removed. As a result, the electric current detection unit 63 can be removed from the case 12. The precharge relay 61 and the resistor 62 can be removed by simply pulling them upward.

Next, effects of this configuration will be listed.

The circuit assembly 10 includes the body 11 and the electrical component device 50 fixed to the body 11. In the circuit assembly 10, the body 11 has the first busbars (conductive path busbars 14), the second busbars (conductive path busbars 14), and the case 12 that accommodates the first busbars and the second busbars. The lid 13 of the case 12 has the first opening portion 13C and the second opening portions 13D into which the electrical component device 50 is insertable. The electrical component device 50 includes relays 51C and 51D, one-side busbars 53 provided at ends on one side of the relays 51C and 51D, other side busbars 54 provided at ends on the other side of the relays 51C and 51D, and the fuses 51E and 51F. The one-side busbars 53 are fixed to the first busbars (conductive path busbars 14) by the first screws B1. The other side busbars 54 are fixed to the second busbars (conductive path busbars 14) by the second screws B2. The one-side busbars 51G and 51H of the fuses 51E and 51F are fixed to the first busbars (conductive path busbars 14) by the fifth screws B5, and the other side busbars 51J and 51K are fixed to the second busbars (conductive path busbars 14) by the fifth screws B5.

With this configuration, the relays 51C and 51D can be attached to the case 12 through the first opening portion 13C, and the fuses 51E and 51F can be attached to the case 12 through the second opening portions 13D, eliminating the need to perform an operation such as opening the case by removing the lid 13 from the case body 16.

The one-side busbars 53 are fastened together with the first busbars (conductive path busbars 14) by the first screws B1. The other side busbars 54 are fastened together with the second busbars (conductive path busbars 14) by the second screws B2. Also, the one-side busbars 51G and 51H of the fuses 51E and 51F are fastened together with the first busbars (conductive path busbars 14) by the fifth screws B5, and the other side busbars 51J and 51K are fastened together with the second busbars (conductive path busbars 14) by the fifth screws B5. This configuration can ensure that the one-side busbars 53, 51G, and 51H are in electrical conduction with the first busbars, and that the other side busbars 54, 51J, and 51K are in electrical conduction with the second busbars.

The electrical component device includes the first insulating member 55A that, in a state in which the electrical component device 50 is fixed to the body 11, covers the relays 51C and 51D from the outside of the case 12 and the second insulating member 55B that covers the fuses 51E and 51F from the outside of the case 12. With this configuration, the first insulating member 55A makes it unlikely for the relays 51C and 51D to be touched, and the second insulating member 55B makes it unlikely for the fuses 51E and 51F to be touched.

The first insulating member 55A has the first exposure holes 55C allowing the heads of the first screws B1 to be exposed to the outside, and the second exposure holes 55D allowing the heads of the second screws B2 to be exposed to the outside. With this configuration, the first screws B1 and the second screws B2 can be attached or detached via the first exposure holes 55C and the second exposure holes 55D.

The opening portions 13B include the first opening portion 13C and the second opening portions 13D, the insulating members 55 include the first insulating member 55A and the second insulating member 55B, and the electrical components 51 include the first electrical component 51A and the second electrical component 51B. The first insulating member 55A covers the first electrical component 51A inserted into the first opening portion 13C from the outside, and the second insulating member 55B covers the second electrical component 51B inserted into the second opening portions 13D from the outside. With this configuration, in a state in which one electrical component 51 is covered with the corresponding insulating member 55, the other electrical component 51 can be exposed. Therefore, an electrical component 51 that needs to be exposed can be exposed while an electrical component 51 that does not need to be exposed is covered.

The first electrical component 51A is fixed to the first insulating member 55A by the third screws B3. With this configuration, it is possible to handle the first electrical component 51A by holding the first insulating member 55A, without coming into direct contact with the first electrical component 51A.

The first insulating member 55A has two through holes 55E serving as holding assistants. With this configuration, the first insulating member 55A can be easily attached to or detached from the case 12.

### Other Embodiments

Embodiments disclosed herein are to be considered in all respects as illustrative and not restrictive. The scope of the disclosure is not limited to the embodiments disclosed herein, and all changes that come within the range defined by the claims or the range of equivalency of the claims are intended to be embraced therein.

Unlike Embodiment 1, a nut may be provided in a leading end portion of a boss through insert molding.

Unlike Embodiment 1, the outer shapes of the first exposure hole and the second exposure hole of the first insulating member are not limited to a rectangular shape.

Unlike Embodiment 1, a configuration in which an insulating member is provided for each relay may be adopted. In this case, a configuration may be adopted in which a plurality of first opening portions may be provided in the lid of the body and one insulating member may be disposed in each of the first opening portions, or a configuration may be adopted in which a plurality of insulating members are arranged side-by-side in one first opening portion.

Unlike Embodiment 1, fuses, resistors, precharge relays, current detection units, voltage detection units, temperature detection units, and the like may be fixed to the insulating member as electrical components. The electrical components are parts that can be replaced when they malfunction.

Unlike Embodiment 1, a screw hole may be formed in the conductive path busbar, and the one-side busbar may be fixed to the conductive path busbar with a first screw. Also, a screw hole may be formed in the conductive path busbar, and the other side busbar may be fixed to the conductive path busbar with a second screw.

Unlike Embodiment 1, a configuration may be adopted in which one side busbar is provided integrally with one end of the relay, or a configuration may be adopted in which an other side busbar is formed integrally with the other end of the relay.

Unlike Embodiment 1, a recess may be formed in the insulating member, and the recess may be used as a holding assistant.

Unlike Embodiment 1, the number of through holes provided in the insulating member and serving as holding assistants may be one, or three or more.

1. A circuit assembly comprising:
a body; and
an electrical component device to be fixed to the body,
wherein the body includes:
a first busbar,
a second busbar, and
a case configured to accommodate the first busbar and the second busbar, the case has an opening portion into which the electrical component device is insertable, the electrical component device includes:
an electrical component,
a one-side busbar provided at one end of the electrical component, and
an other-side busbar provided at another end of the electrical component, the one-side busbar is fixed to the first busbar by a first screw, and the other-side busbar is fixed to the second busbar by a second screw.

2. The circuit assembly according to claim 1,
wherein the one-side busbar is fastened together with the first busbar by the first screw, and
the other-side busbar is fastened together with the second busbar by the second screw.

3. The circuit assembly according to claim 1,
wherein the electrical component device includes an insulating member configured to cover at least a portion of the electrical component from outside of the case in a state in which the electrical component device is fixed to the body.

4. The circuit assembly according to claim 3,
wherein the insulating member has a first exposure hole allowing a head of the first screw to be exposed to the outside, and a second exposure hole allowing a head of the second screw to be exposed to the outside.

5. The circuit assembly according to claim 3,
wherein there are a plurality of the opening portions, including a first opening portion and a second opening portion,
there are a plurality of the insulating members, including a first insulating member and a second insulating member,
there are a plurality of the electrical components, including a first electrical component and a second electrical component,
the first insulating member covers the first electrical component inserted into the first opening portion from the outside, and
the second insulating member covers the second electrical component inserted into the second opening portion from the outside.

6. The circuit assembly according to claim 3,
wherein the electrical component is fixed to the insulating member by a third screw.

7. The circuit assembly according to claim 3,
wherein the insulating member has one or more recesses or through holes serving as holding assistants.
